(19) United States
(12) Patent Application Publication
(10) Pub. No.: US 2007/0273392 A1
(43) Pub. Date: Nov. 29, 2007

(54) Implant for Intracorporal, Telemetric Measurement

(76) Inventors: Volker Bodecker, Hannover (DE); Axel Niemeyer, Bielefeld (DE); Stefan Meyer, Breidenbach (DE); Max G. Ostermeier, Hannover (DE); Bernhard Wagner, Wunstorf (DE)

Correspondence Address: PHILIP S. JOHNSON;JOHNSON & JOHNSON, ONE JOHNSON & JOHNSON PLAZA, NEW BRUNSWICK, NJ, 08933-7003, US

(21) Appl. No.: 10/579,265

(22) PCT Filed: Nov. 9, 2004
(86) PCT No.: PCT/EP04/12671

§ 371 Date: May 4, 2007

(30) Foreign Application Priority Data
Nov. 14, 2003 (DE) 103 53 143.2

(51) Int. Cl. G01R 27/26

(52) U.S. Cl. 324/654

(57) ABSTRACT

An implant for an intracorporal, telemetric measurement with a sensor device (1) and an inductive coil (2), which is connected to the sensor device (1) via electrical connection lines (4) being arranged on a longitudinal carrier (3), and a covering (5) by means of which the sensor device (1), the carrier (3) with the connection lines (4) and the coil (2) are encapsulated, wherein the carrier (3) for the electrical connection lines (4) comprises such a dimensioned rigidity that the sensor device (1), being fixedly bonded to one carrier end, is guided by the carrier (3) during implantation to the target position and is held in position at the target position, and that the covering part (6) encapsulating the coil (2) is provided for a subcutaneous fastening.

The invention relates to an implant for an intracorporal telemetric measurement according to the preamble of patent claim 1.

In such an implant, known from U.S. Pat. No. 6,083,174, a sensor device with an inductive coil is electrically connected via an electric line being arranged on a longitudinal carrier. The sensor device and the carrier with the connection lines and the coil are encapsulated in a covering. The sensor device as well as the coil and the electrical connection conductors are arranged on a flexible foil. By means of the inductive coupling of the coil as well the energy supply of the sensor device as the telemetric transmission of the data measured by the sensor device is achieved. With the known implant, intracranial pressure measurements can be carried out.

It is the subject of the invention to create an implant of the above-mentioned type the implantation of which especially in corporeal interiors, such as interiors of the brain, is facilitated.

This object is achieved according to the invention by the characterizing features of patent claim 1.

According to the invention, the carrier comprises for the electrical connection lines such a stiffness and rigidity that the sensor device which is fixedly bonded to one carrier end is guided by means of the carrier during implantation to the target position and is positioned, especially held in position, at the target position. Therefore, the covering part which encapsulates the inductive coil is provided for a subcutaneous mounting, especially an epidural fixation.

With the implanted sensor device, which is connected rigidly with the covering part which encapsulates the inductive coil via the relatively stiff carrier, intracranial, e.g. intraparenchymal or intraventricular pressure measurements can be carried out.

For an appropriate subcutaneous, especially epidural arrangement of the inductive coil, the coil with its plane may, after the positioning of the sensor device at the target position, be bended relative to the carrier at an angle <180°, especially from 60° to 120°. Between the sensor device and the coil, there are preferably two electrical connection lines arranged at the carrier, especially for a digital data transmission. The same serve for energy supply of the sensor device and for the transmission of the measurement data being processed for the telemetry.

The carrier may for example be formed as thin polyimide foil which for stiffening may comprise a cambered form. The carrier may also be rod-shaped with an rectangular cross-section or a circle segment cross-section.

It is also possible to provide a stiffening foil in the covering with which the carrier and the connection lines being arranged thereon are encapsulated.

However, a flat form of the carrier and of the covering which encapsulates the latter is preferred.

The sensor device includes at least one sensor, by means of which physical quantities may be measured at the target position. Preferably, the sensor device comprises at least one pressure sensor and is possibly an additional temperature sensor. The telemetry electronics can be arranged within the sensor device, for processing the measuring signals of the sensor for a telemetric transmission through the inductive coil. The at least one pressure sensor and the telemetry electronics may be arranged in a measurement chip. The covering consists of a biocompatible material, such as silicon. In the range of the one or more pressure sensors, the covering may be formed in such a way that the same forwards the pressure to be measured to at least one pressure sensor. For example, at least in the range of the pressure sensor a flexible covering may be applied in which a pressure transmitting medium, preferably a gel, an oil based on silicon or the like is arranged.

By means of the figures, the invention is explained in more detail by means of exemplary embodiments.

It shows:

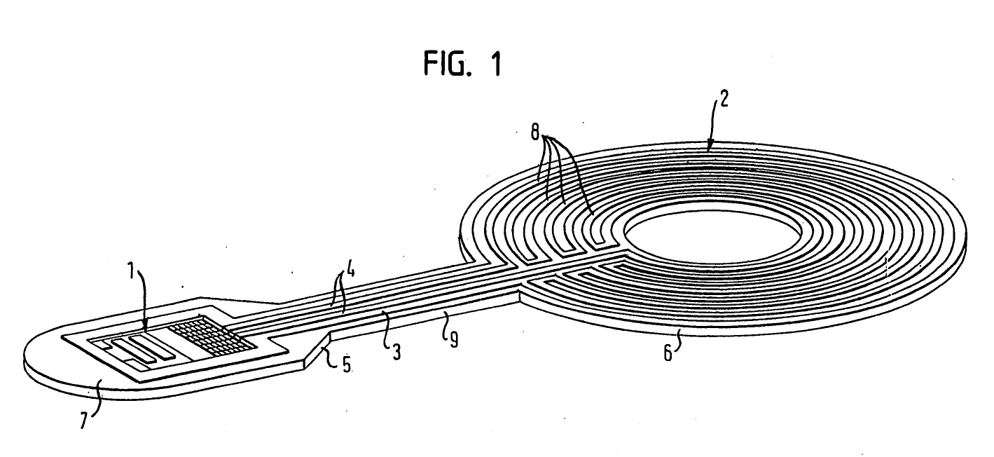

FIG. 1 an exemplary embodiment of the invention with a covering being open in upward direction;

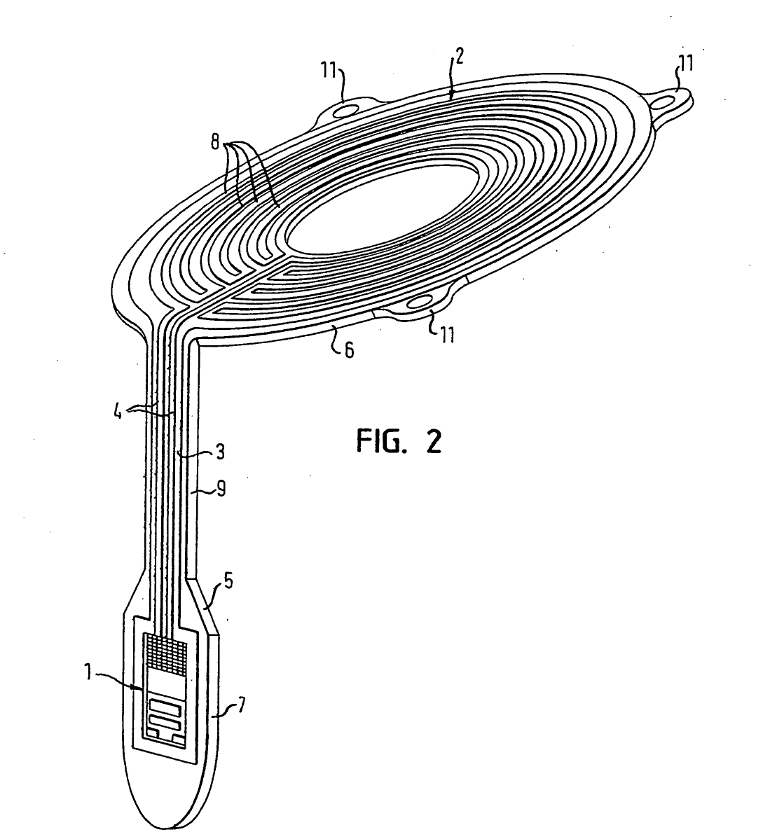

FIG. 2 a second exemplary embodiment of the invention with an open covering; and

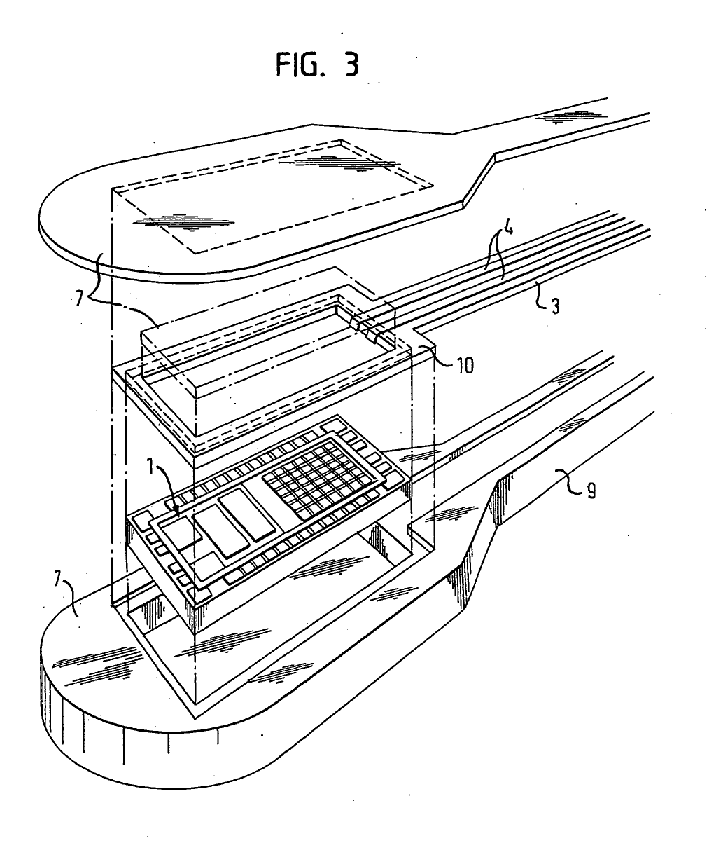

FIG. 3 an exploded view of the exemplary embodiments of FIGS. 1 and 2 in the range of the sensor device.

The exemplary embodiments of an implant for an intracorporal telemetric measurement illustrated in the figures include a sensor device 1 and an inductive coil 2, which are connected to one another via electrical connection lines 4. In the illustrated exemplary embodiments, there are provided two electrical connection lines 4. The electrical connection lines are preferably applied as metallizations of noble metal, especially gold, on a longitudinal carrier 3. The longitudinal carrier 3 may be formed as a foil of an appropriate plastic, for example polyimide or also as a longitudinal rod. As shown in the figures, the carrier is preferably formed as flat carrier with an rectangular cross-section.

The carrier 3 possesses a set stiffness which is dimensioned in such a way that the sensor device 1 being rigidly bonded to one carrier end is guided during implantation to the target position by means of the carrier 3 and is held in position at the target position. The carrier 3 therefore is formed sufficiently stiff, yet still flexible enough that the implantation may be carried out without irritation of the surrounding corporal tissue. At the other end, the carrier 3 is rigidly bonded to the covering part 6 which encapsulates the coil 2. The covering part 6 is provided for a subcutaneous mounting and e.g. at an intracranial pressure measurement for an epidural arrangement and fixation.

For a rigid connection of the sensor device 3 with the carrier end, there is provided at the carrier 3 a frame 10 being rigidly connected with the carrier end 3. This frame 10 may be formed in one piece of the carrier material 3. In the assembled condition, the sensor device 1 is placed within the rectangular opening of the frame.

The individual parts of the implant are encapsulated by a bio-compatible covering 5, for example of silicon. This covering 5, which especially in the range of the sensor device may be formed as a gel or oil including flexible foil comprising the covering part 6 encapsulating the coil 2 and a covering part 9, encapsulating the carrier and the connection lines 4 being arranged thereon and a covering part 7 encapsulating the sensor device 1.

The covering part 7 is formed in such a way that it is permeable for the physical quantity to be measured at the target position. Preferably it acts as a pressure transmitting medium for a pressure measurement, for example silicon or a foil covered gel.

In the exemplary embodiment shown in FIG. 1, the sensor device 1 and the coil windings 8 of the inductive coil 2 are located in a common plane. The coil windings may be formed as electrical tracks, metallizations, thin wires and the like. In the exemplary embodiment illustrated in FIG. 2, the carrier 3 with the connection lines 4 being arranged thereon and the sensor device 1 extend in an angle of approximately 90° relative to the plane in which the coil windings 8 are arranged. This angled arrangement is generated after the implantation of the sensor device 1 and the carrier 3 by bending the coil assembly. Depending on the location of the target position and the position in which the inductive coil 2 is arranged subcutaneously, the angle between the carrier 3 and the plane of the coil windings 8 will be dimensioned <180°, especially to a dimension in the range from 60° to 120°.

For a facilitated implantation, the covering part 6 and the coil assembly in the covering part 6 are formed sufficiently flexible for a folding or for rolling. For a subcutaneous fixation, the covering part 6 may comprise fixing elements 11, by which for example by sewing a fixation of the coil and thus of the implant is achieved.

### List of Reference Numbers

1 sensor device

2 inductive coil

3 carrier for electrical connection lines

4 electrical connection lines

5 covering (encapsulation)

6 covering part for the coil

7 covering part for the sensor device

8 coil windings

9 covering part for the carrier

10 frame

11 fixing elements

1. An implant comprising
a sensor device being fixedly connected to a first end of a longitudinal carrier;
an inductive coil connected to the sensor device via electrical connection lines that are arranged on the longitudinal carrier; and
a covering encapsulating the sensor device, the carrier with the connection lines and the coil;
wherein the carrier has a sufficient rigidity such that the sensor device is adapted to be guided by the carrier during implantation to the target position and held in position at the target position, and that the covering part has means for providing a subcutaneous fastening.

2. The implant according to claim 1, wherein
the carrier is arranged at an angle <180°, relative to the plane, in which the coil windings of the inductive coil are arranged.

3. The implant according to claim l , wherein
there are provided two connection lines between the coil and the sensor device.

4. The implant according to claim 1, wherein
the carrier flat.

5. The implant according to claim 1, further comprising
a stiffening foil being provided in the covering part.

6. The implant according to claim 5, wherein
the carrier formed as at least one of a rod and a foil.

7. The implant according to claim 6, wherein
the carrier (3) is formed as a stiffened foil with at least one of a rectangular and a circle-segment-like cross-section.

8. The implant according to claim 1, wherein
a frame is fastened at the first end of the carrier, the sensor device positively fits within the frame.

9. The implant according to claim 8, wherein
the frame is formed one piece with the carrier.

10. The implant according to claim 1, wherein
the carrier is formed as a common carrier for the electrical connection lines and the coil windings.

11. The implant according to claim 1, wherein
the sensor device comprises at least one pressure sensor.

12. The implant according to claim 1, wherein
the covering part encapsulating the coil is adapted to be arranged in an interior of the brain.

13. The implant according to claim 12, wherein
the encapsulating material of the covering part covering the sensor device is formed as a pressure transmitting medium.

14. The implant according to claim 1,
wherein the sensor device is adapted to be positioned for at least one of an intraparenchymal and a intraventricular pressure measurement.

15. An implant according to claim 2, wherein the angle is from 60° to 120°.

16. An implant according to claim 12, wherein the covering part encapsulating the coil is adapted to be arranged in the epidural.

17. An implant according to claim 13, wherein the encapsulating material of the covering part covering the sensor device is made of silicon.
